(19) United States
(12) Patent Application Publication
(10) Pub. No.: US 2016/0053374 A1
(43) Pub. Date: Feb. 25, 2016

(54) GAS SPRAYER AND THIN FILM DEPOSITING APPARATUS HAVING THE SAME

(71) Applicant: AVACO CO., LTD, Daegu (KR)

(72) Inventors: Byeong-Eok HWANG, Daegu (KR); Seung-Hyun JANG, Daegu (KR); Kyung-Han KIM, Daegu (KR); Woo-Jin CHOI, Daegu (KR); Jong-Hak KIM, Daegu (KR)

(21) Appl. No.: 14/779,595

(22) PCT Filed: Mar. 18, 2014
(86) PCT No.: PCT/KR2014/002256

§ 371 Date: Sep. 24, 2015

(30) Foreign Application Priority Data
May 14, 2013 (KR) 10-2013-0054139

(51) Int. Cl. C23C 16/455; C23C 16/458

(52) U.S. Cl. CPC C23C 16/45559; C23C 16/45563; C23C 16/45561; C23C 16/4582

(57) ABSTRACT

A thin film depositing apparatus includes a gas sprayer which is capable of forming a uniform thin film and reducing processing time. Such a gas sprayer includes an upper plate and a bottom plate. The upper plate includes a plurality of gas injection inputs. The bottom plate is coupled to the upper plate to form diffusion space therebetween, and includes a first gas spraying holes for injecting gas in the diffusion space which is injected through the plurality of first gas injection inputs. Herein, the plurality of first gas injection inputs is arranged symmetrically with respect to each other.

### TECHNICAL FIELD

Exemplary embodiments of the present invention relate to a gas sprayer and a thin film depositing apparatus having the same. More particularly, exemplary embodiments of the present invention relate to a gas sprayer and a thin film depositing apparatus having the same used in manufacturing semiconductor or flat-panel display.

### BACKGROUND ART

In general, a thin film is used for a dielectric material of a semiconductor element, a transparent electric conductor of liquid crystal display, and a protective layer of a thin film electroluminescent display element. Also, CVD (Chemical Vapor Deposition), ALE (Atomic Layer Epitaxy), ALS (Atomic Layer Deposition), etc. are used as a deposition method to form such a thin film.

In general, a substrate supporter and a gas sprayer is disposed in a chamber to deposit such a thin film, and a thin film is deposited by spraying gas toward substrate to be treated of upper surface of the substrate supporter through the gas sprayer.

However, as the size of flat panel display becomes larger, gas sprayed by the gas sprayer is not uniform which causes defect, and it is requested a thin film depositing apparatus with uniform sprayer.

### DISCLOSURE

### Technical Problem

Therefore, the technical problem of the present invention is to provide a gas sprayer capable of solving such a problem.

Also, another technical problem of the present invention is to provide a thin film depositing apparatus including such a gas sprayer.

### Technical Solution

In order to solve this problem, a gas sprayer according to an exemplary embodiment of the present invention includes an upper plate and a bottom plate. The upper plate includes a plurality of first gas injection inputs. The bottom plate is coupled to the upper plate to form diffusion space therebetween, and includes a plurality of first gas spraying holes to spray gas in the diffusion space which is injected through the plurality of first gas injection inputs.

Preferably, the plurality of first gas injection inputs may be arranged symmetrically with respect to each other.

Also, the gas sprayer may further include a first pipe connecting structure to inject external gas to the plurality of first gas injection inputs. Herein, a distance from a first input in in which external gas is injected to the plurality of first gas injection inputs of the first pipe connecting structure has the same structure.

Also, the gas sprayer may further include a first connecting member to couple the upper plate and the first pipe connecting structure, and the first connecting member may couple a first output of the first pipe connecting structure to the plurality of first gas injections.

Meanwhile, the bottom plate may further include a diffusion holes and a second gas spraying holes. The diffusion holes traverse both sides of the bottom plate between the first gas spraying holes. The second gas spraying holes spray the injected gas from the diffusion holes into the lower portion

Herein, the upper plate includes a plurality of second gas injection inputs, the plurality of second gas injection inputs may be connected to the diffusion holes.

Meanwhile, the plurality of second gas injection inputs is formed symmetrically on both sides of the upper plate, the both sides being opposite to each other.

Also, the gas sprayer may further include a second pipe connecting structure for injecting external gas to the plurality of second gas injection inputs, and a distance from a second input in which external gas is injected to the plurality of second gas injection inputs of the second pipe connecting structure may be formed in the same structure.

Also, the gas sprayer is attached on upper surface of the upper plate, and further includes a second connecting member which connects the upper plate to the second pipe connecting structure, and the second connecting member may connect a second output of the first pipe connecting structure to second plurality of gas injections.

In order to solve this problem, a thin film depositing according to an exemplary embodiment of the present invention includes apparatus includes a chamber, a substrate supporter, and a gas sprayer. The substrate supporter supports substrate within the chamber. The gas sprayer sprays gas toward the substrate supporter from the top of the substrate supporter. The gas sprayer includes an upper plate and a bottom plate. The upper plate includes a plurality of first gas injection inputs which is arranged symmetrically with respect to each other. The bottom plate is coupled to the upper plate forming diffusion space therebetween, and includes a plurality of first gas spraying holes for spraying existing gas in diffusion space which is injected from the plurality of first gas injection inputs.

Meanwhile, the gas sprayer further includes a firs pipe connecting structure for injecting external gas to the first gas injection inputs, and a distance from a first input in which external gas is injected to the plurality of first gas injection inputs of the first pipe connecting structure may be formed in the same structure.

Also, the thin film depositing apparatus further includes a first tank in which a source gas and carrier gas is mixed, and a second tank in which carrier gas is mixed, the first and second tanks are connected to an input of the first pipe connecting structure through a valve capable of adjusting a flow rate.

Also, the bottom plate may further include a diffusion holes that traverses both sides of the bottom plate between the first gas spraying holes, the both sides being opposite to each other, and a second gas spraying holes for spraying the injected gas from the diffusion holes into a lower portion, and the plurality of second gas injection inputs are connected to the diffusion holes.

Also, the gas sprayer further includes a second pipe connecting structure for injecting external gas to the plurality of second gas injection inputs, a distance from a second input in which external gas is injected to the plurality of second gas injection inputs of the second pipe connecting structure may be formed in the same structure.

Also, the thin film depositing apparatus further includes a third tank in which a source gas and carrier gas is mixed and a fourth tank in which a carrier gas is mixed, the third and fourth tanks are connected to an input of the second pipe connecting structure through a valve capable of adjusting a flow rate.

Also, the thin film depositing apparatus may further include at least any one of the groups of a first to fourth tanks group, a fifth to eighth tanks group in which the first and second tanks that are connected to a portion of the plurality of first gas injection inputs where a source gas and carrier gas are mixed and stored in the first tank and carrier gas is mixed and stored in the second tank, the third and fourth tanks that are connected to the remaining portion of the plurality of first gas injection inputs where a source gas and carrier gas are mixed and stored in the third tank and carrier gas is mixed and stored in the fourth tank, a fifth and sixth tanks that are connected to a portion of the plurality of second gas injection inputs where a source gas and carrier gas are mixed and stored in the fifth tank and carrier gas is mixed and stored in the sixth tank, and a seventh and eighth tanks that are connected to the remaining portion of the plurality of second gas injection inputs where a source gas and carrier gas are mixed and stored in the seventh tank and carrier gas is mixed and stored in the eighth tank.

### Advantageous Effects

According to an exemplary embodiment of the present invention, a gas sprayer and a thin film depositing apparatus, when they are applied to a large size substrate, reduces a gas diffusion time within diffusion space, and forms a relative uniform thin film in large size substrate even though an amount of injected gas is not much by injecting gas to diffusion space through plurality of diffused gas injection inputs without complex processing such as auxiliary diffusion space to distribute a gas uniformly.

Also, the plurality of first gas injection inputs are arranged symmetrically with respect to each other, in case that a gas is injected to the first gas injection inputs through a first pipe connecting structure in which a distance from a first input that external gas is injected to the plurality of first gas injection inputs has the same structure, a more uniform thin film is formed as the gas reaches the same time point to the plurality point of the diffusion space since movement path from the first input to the plurality of first gas injection inputs becomes same.

Also, the bottom plate further includes a diffusion holes and a second gas spraying holes, the diffusion holes traverse both sides of the bottom plate between the first gas spraying holes, the both sides being opposite to each other, the second gas spraying holes spray two types of gases which should not be mixed in advance through each of a first gas spraying holes and the second gas spraying holes.

Also, the upper plate includes a plurality of second gas injection inputs, in case that the plurality of second gas injection inputs are connected to the diffusion holes, it is possible to facilitate the pipe structure for injecting gas since the first pipe connecting structure and the second pipe connecting structure are formed on upper surface of the upper plate through the upper surface of the upper plate.

Also, the plurality of second gas injection inputs are aligned symmetrically with respect to each other, in case that a gas is injected to the second gas injection inputs through a second pipe connecting structure in which distance from a second input that external gas is injected to the plurality of second gas injection inputs has the same structure, a more uniform thin film is formed as the gas reaches the same time point to the plurality point of the diffusion space since movement path from the second input to the plurality of second gas injection inputs becomes same.

Also, in case that each of the first pipe connecting structure and the second pipe connecting structure is connected to the upper plate by using the first connecting member and second connecting member, it is possible to simplify formation of pipe connecting structure as well as to attach easily pipe connecting structure to upper plate since plurality of gas injection inputs are connected to an output of single pipe connecting structure.

Also, unlike conventional thin film depositing apparatus, in case that an auxiliary carrier gas tank is added, a uniform thin film is formed by spraying gas more effectively within gas sprayer since a pressure is improved by increasing carrier gas.

### DESCRIPTION OF DRAWINGS

FIG. 1 is a perspective view showing of a gas sprayer according to an exemplary embodiment of the present invention;

FIG. 2 is a cross sectional view taken along section line of I-I′ of FIG. 1;

FIG. 3 is a cross sectional view taken along section line of II-IF of FIG. 1;

FIG. 4 is a bottom view of the gas sprayer of FIG. 1;

FIG. 5 is a sectional view showing schematically a thin film depositing apparatus having a gas sprayer according to an exemplary embodiment of the present invention;

FIG. 6 is a figure showing simulation result of a gas sprayer having eight gas injection inputs according to an exemplary embodiment of the present invention;

FIG. 7 is a figure showing a simulation result of a gas sprayer having sixteen gas injection inputs according to an exemplary embodiment of the present invention;

FIG. 8 is a figure showing simulated thickness result of thin film formed by a gas sprayer having eight gas injection inputs according to an exemplary embodiment of the present invention of FIG. 6;

FIG. 9 is a figure showing simulated thickness result of thin film formed by a gas sprayer having sixteen gas injection inputs according to an exemplary embodiment of the present invention of FIG. 7.

### MODE FOR INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that, although the terms first, second, third etc. may be used herein to describe various elements, components, regions, layers and/or sections, these elements, components, and/or sections should not be limited by these terms. These terms are only used to distinguish one element, component, region, layer or section from another region, layer or section. Thus, a first element, component, or section discussed below could be termed a second element, component, or section without departing from the teachings of the present invention.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

For convenience, same numerals are used for identical or similar elements of an apparatus of cutting a tempered substrate and the conventional one.

Hereinafter, with reference to the drawings, preferred embodiments of the present invention will be described in detail

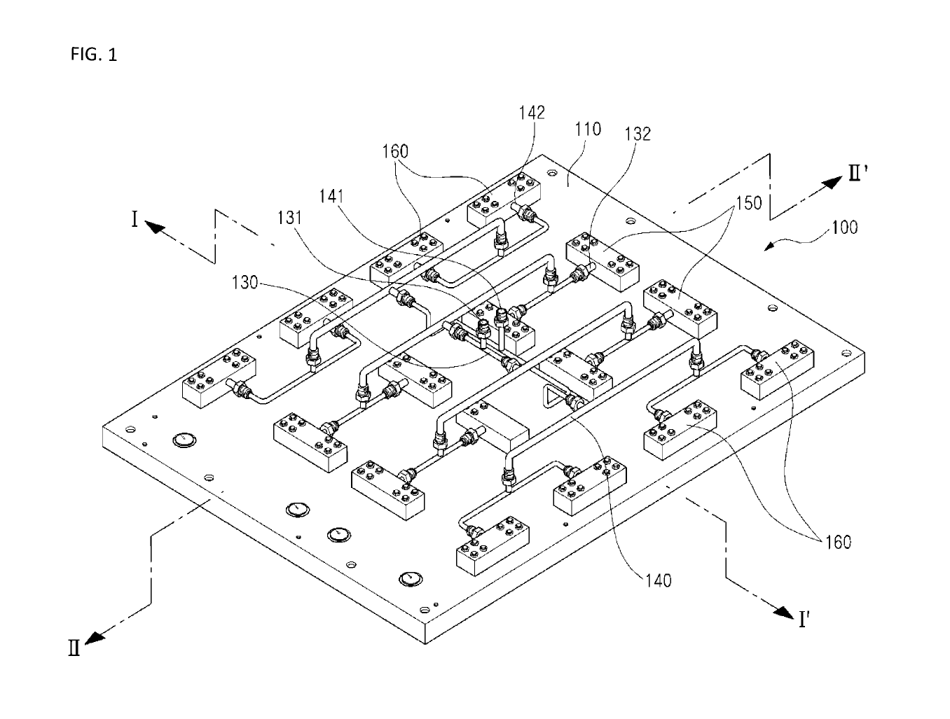

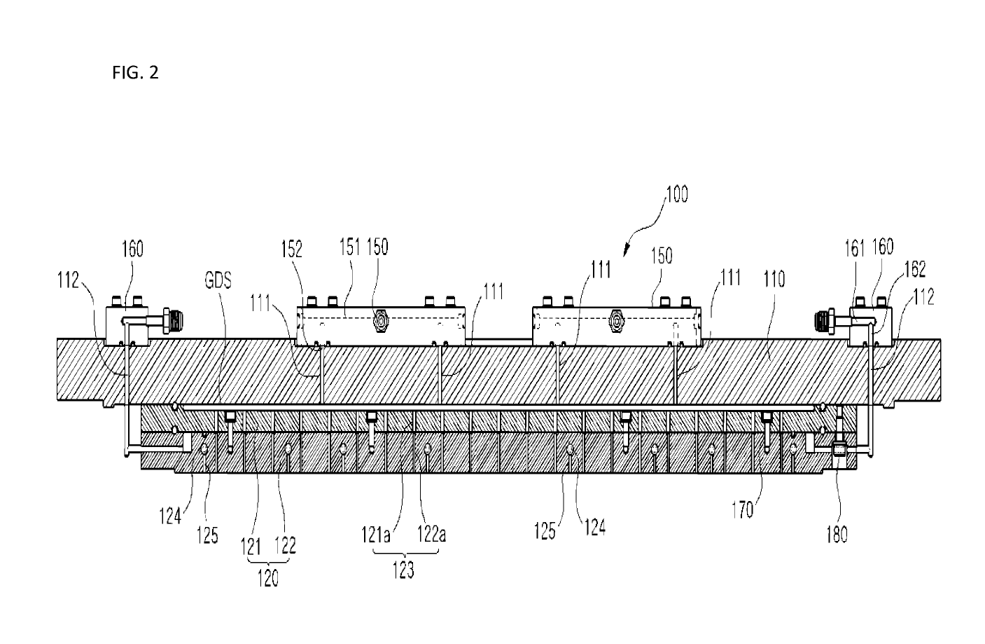

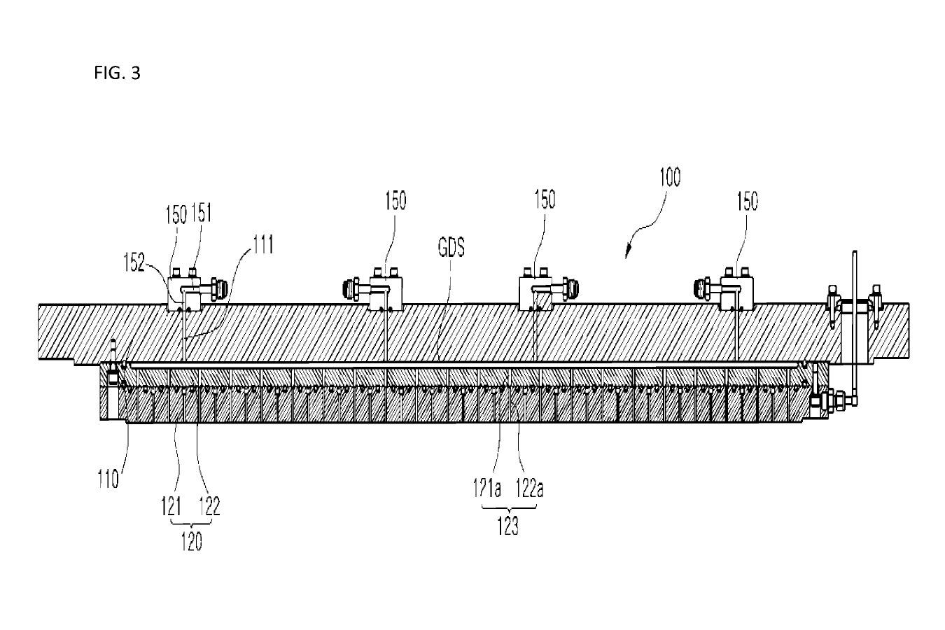

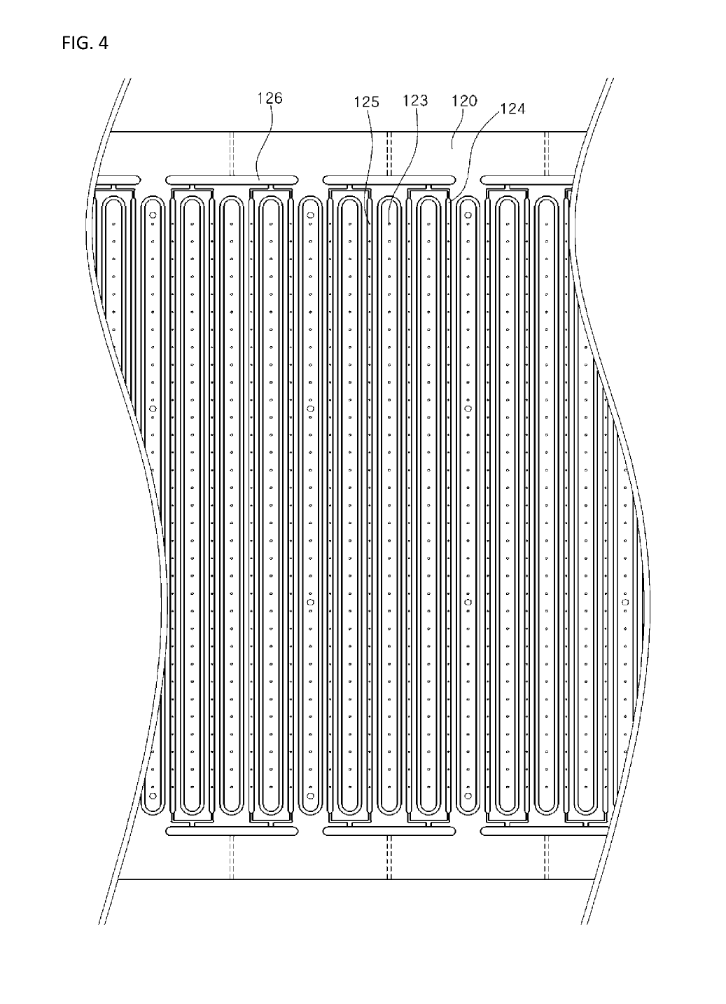

FIG. 1 is a perspective view showing a gas sprayer according to an exemplary embodiment of the present invention. FIG. 2 is a cross sectional view taken along section line of I-I′ of FIG. 1, FIG. 3 is a cross sectional view taken along section line of II-IF of FIG. 1, and FIG. 4 is a bottom view of the gas sprayer of FIG. 1.

Referring to FIGS. 1 to 4, a gas sprayer 100 according to an exemplary embodiment of the present invention includes an upper plate 110 and a bottom plate 120.

The upper plate 110 includes a plurality of first gas injection inputs 111. Herein, the plurality of first gas injection inputs 111 may be aligned symmetrically with respect to each other. When the plurality of first gas injection inputs are aligned symmetrically, gas sprayed on top of a substrate is sprayed uniformly, also pipe connecting structures 130 and 140 which will be explained later may be connected more effectively to the plurality of first gas injection inputs. For example, the upper plate 110 may be formed with a material such as SUS.

The bottom plate 120 is coupled to the upper plate to form a diffusion space GDS therebetween, and includes a plurality of first gas spraying holes 123 for spraying existing gas in the diffusion space GDS that is injected through the plurality of first gas injection inputs 111. For example, the plurality of first gas spraying holes 123 may be arranged in a matrix form. Also, the bottom plate 120 may be formed with a material such as SUS likewise the upper plate.

The bottom plate 120 may be coupled to the upper plate 110 through a second screw 180. The second screw 180 is coupled outside of the upper plate 110 and bottom plate 120.

The bottom plate 120 includes two plates, a first plate 121 and a second plate 122, and they are coupled to each other through a first screw 170. The first plate 121 includes a first hole 121a having a relatively large diameter, the second plate 122 includes a second hole 122a having a relatively small diameter, and the first hole 121a and the second hole 122a are connected to each other to form the first gas spraying holes 123.

In this way, a flow rate of gas spray is increased when a gas is sprayed from the diffusion space GDS to a bottom of reaction space of the bottom plate 120 through the first gas spraying holes 123 in which diameter is gradually decreased.

In this way, when the bottom plate 120 is formed with two plates, the firs plate 121 and second plate 122, a process of the first gas spraying holes with diameter increasing gradually is easily done, as well as, a deflection of center portion of the bottom plate is reduced when a size of the bottom plate is increased because size of substrate to be treated is increased. However, unlike to the exemplary embodiment of the present invention, the upper plate 120 may be formed in single plate. Also, diameters of the first hole 121a and the second hole 122a may be identical in length.

Also, the gas sprayer 100 may further include a first pipe connecting structure 130 for injecting external gas to the plurality of first gas injection inputs. Herein, distance from a first input 130 in which external gas is injected to the plurality of first gas injection inputs 111 of the first pipe connecting structure 130 has the same structure.

In other words, the first pipe connecting structure includes a first input 131 in which external gas is injected, a distance from the first input to plurality of first outputs 121 is identical in length. Therefore, gas injected to the first input 131 reaches at the same time to the plurality of first outputs 132, gas is injected to diffusion space GDS in number of points, and therefore relative thin film is deposited.

Also, the gas sprayer further includes a first connecting member 150 attached on upper surface of the upper plate 110 to couple the upper plate 110 and the first pipe connecting structure 130, the first connecting member 150 may connect the plurality of first gas injection inputs 111 to an output 132 of single first pipe connecting structure 130.

For this reason, the first connecting member 150 may have rod-shaped as an example, and includes a first horizontal hole 151 formed to horizontal direction of the rod-shaped and a vertical hole 152 connected to the first horizontal hole 151. The first horizontal hole 151 is connected to a first output 132 of the first pipe connecting structure 130, and plurality of vertical holes 152 connect the first horizontal hole 151 and the plurality of first gas injection inputs 111.

For example, the first connecting member 150 may be formed using a SUS, and coupled to the upper surface of the upper plate 110 through screw.

Meanwhile, in the process of forming a thin film on a substrate to be treated, in some cases, source gas of various kinds is sprayed to upper surface of the substrate to be treated. However, a reaction occurs when source gas of various kinds is met, and in some case, separate spraying to a reaction space between the bottom of gas sprayer and substrate to be treated since reaction occurs to each other when such a two kind of gas is injected to the gas diffusion space GDS.

For this reason, the bottom plate 120 may further include a diffusion holes 124 and a second gas spraying holes 125.

The diffusion holes 124 traverse both sides of the bottom plate 120, the both sides being opposite to each other. The second gas spraying holes 125 spray gas to the diffusion holes 124 into the lower.

In more detail, for example, the diffusion holes 124 may be formed traversing both sides of the second plate 122 of the bottom plate 120, the both sides being opposite to each other. Each of plurality of diffusion holes 124 are extended to row or column direction of the first gas spraying holes 123 that are arranged in a matrix form, the second gas spraying holes 125 is extended to the bottom of each of the diffusion holes 124, and gas injected to the diffusion holes 124 is sprayed to the reaction space. The diffusion holes 124 are connected to a lateral diffusion space 126 of lateral surface of the bottom plate 120. As shown, plurality of diffusion holes 124 may be connected to a lateral diffusion space 126. The lateral diffusion space 126 is formed symmetrically to both sides which is opposed to the bottom plate 120, and is connected to the plurality of diffusion holes 124 formed symmetrically.

Also, the upper plate 110 includes plurality of second gas injection inputs 112 formed symmetrically in both sides which is opposed to the upper plate 110, the plurality of second gas injection inputs 112 may be connected to the diffusion holes 124 through the lateral diffusion space 126. In other words, the second gas injection inputs 112 is connected to the lateral diffusion space 126 to supply gas to the lateral diffusion space 125, the gas injected to the lateral diffusion space 126 is sprayed to reaction space through the second gas spraying holes 125.

Also, the upper plate 110 may further include a second pipe connecting structure 140 for injecting external gas to the plurality of second gas injection inputs 112, distance from a second input 140 in which external gas is injected to the plurality of second gas injection inputs 112 the second pipe connecting structure 140 may be formed in the same structure.

In other words, the second pipe connecting structure 140 includes a second input 141 in which external gas is injected and a plurality of second outputs 142, a distance from one second input 141 to the plurality of second outputs 142 is identical in length. Thereby, gas injected to the second input 141 reaches to the plurality of second outputs at the same time, and therefore, it is possible to form a relatively uniform thin film.

Also, the gas sprayer 100 is coupled to upper surface of the upper plate 110 and further includes a second connecting member 160 which connects the upper surface of the upper plate 120 to the second pipe connecting structure 140, the second connecting member may connect the output 142 of the second pipe connecting structure 140 to the plurality of second gas injection inputs.

For this reason, the second connecting member 160 may have a rod-shaped form as an example, and may include a second horizontal hole 161 formed in horizontal direction and a second vertical hole 162 connected to the second horizontal hole 161. The second horizontal hole 161 is connected to the second output 142 of the second pipe connecting member 140, and plurality of second vertical holes 162 connect the second horizontal hole 161 to each of the plurality of second gas injection inputs 112.

For example, the second connecting member 160 may be formed using a SUS, and coupled to upper surface of the upper plate 110 through a screw

In this way, in case that each the first pipe connecting structure 130 and the second pipe connecting structure 140 are connected to upper surface of the upper plate 110 by using the first connecting member 150 and the second connecting member 161, it is possible to simplify a structure of pipe connecting structures 130 and 140 since plurality of gas injection inputs are connected to single pipe connecting structures 130 and 140, as well as, to easily couple pipe connecting structures 130 and 140 and the upper plate 110.

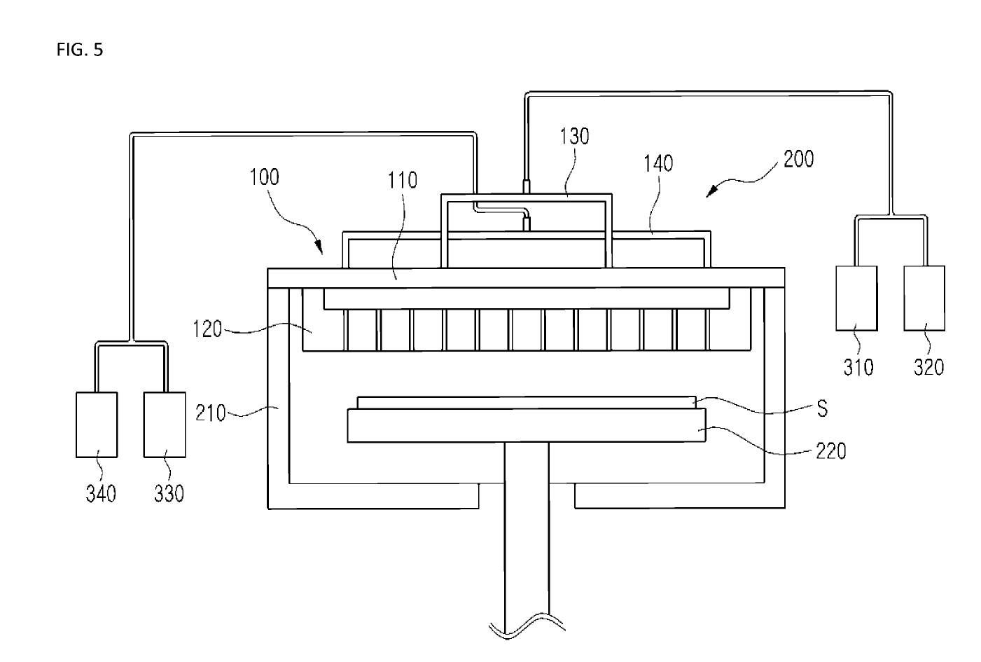

FIG. 5 is a sectional view showing schematically a thin film depositing apparatus having a gas sprayer according to an exemplary embodiment of the present invention.

Referring to FIG. 5, a thin film depositing apparatus 200 according to an exemplary embodiment of the present invention includes a chamber 210, a substrate supporter 220, and a gas sprayer 100.

The substrate 200 supports a substrate to be treated S within the chamber 210. The substrate supporter 200 is configured to be raised or lowered by a driving part (not shown), when the substrate to be treated S is loaded in lowered state, the substrate supporter is raised, and forms a reaction space since it is separated certain distance from the gas sprayer 100.

The gas sprayer 100 sprays gas into upper surface of the substrate supporter 220. The gas sprayer 100 includes an upper plate 110 and a bottom plate 120. The structure of the gas sprayer is described before, and duplicated explanation is skipped.

Meanwhile, the first pipe connecting structure 130 is connected to the plurality of gas tanks. For example, the first pipe connecting structure 130 is connected to a first gas tank 310 and a second gas tank 320. Likewise, the second pipe connecting structure 40 is connected to plurality of gas tanks. For example, the second pipe connecting structure 130 is connected to a third gas tank 330 and a fourth gas tank 340.

Herein, the first gas tank 310 and the third gas tank 330 stores source gas and mixed gas including carrier gas to transfer the source gas, the second gas tank 320 and the fourth gas tank 340 stores carrier gas.

Each of the gas tanks 310 320 330 and 340 is connected to the pipe connecting structures 130 and 140 through pipes formed with valve.

In this way, unlike conventional depositing apparatus, in case that an auxiliary carrier gas tank is added, a uniform thin film is formed by spraying gas more effectively within gas sprayer since pressure is improved by increasing carrier gas though sprayed amount of source gas is small.

In other words, when substrate becomes larger, uneven of a film between center portion and lateral side of substrate to be treated gets worse when small amount of source gas and mixed gas of carrier gas is injected. Herein, a uniform film may be formed by increasing an amount of a carrier gas.

Meanwhile, although not shown, the thin film depositing apparatus may further include at least any one of the groups of a first to fourth tanks group, a fifth to eighth tanks group in which the first and the second tanks that are connected to a portion of the plurality of first gas injection inputs where a source gas and carrier gas are mixed and stored in the first tank and mixed gas with carrier gas is stored in the second tank, the third and fourth tanks that are connected to the remaining portion of the plurality of first gas injection inputs where a source gas and carrier gas are mixed and stored in the third tank and mixed gas with carrier gas is stored in the fourth tank, a fifth and sixth tanks that are connected to a portion of the plurality of second gas injection inputs where a source gas and carrier gas are mixed and stored in the fifth tank and mixed gas with carrier gas is stored in the sixth tank, and a seventh and eighth tanks that are connected to the remaining portion of the plurality of second gas injection inputs where a source gas and carrier gas are mixed and stored in the seventh tank and mixed gas with carrier gas is stored in the eighth tank.

In more detail, in FIGS. 1 to 3, the first gas injection inputs 111 is connected to single pipe connecting structure, the single pipe connecting structure connects tank storing source gas and mixed gas with carrier gas and tank storing carrier gas, the first gas injection inputs 111 are divided in groups with identical number, each group is connected to single pipe connecting structure, and each pipe connecting structure is connected to a tank storing source gas and mixed gas with carrier gas.

Also, the second gas injection inputs 111 may be formed in the same structure.

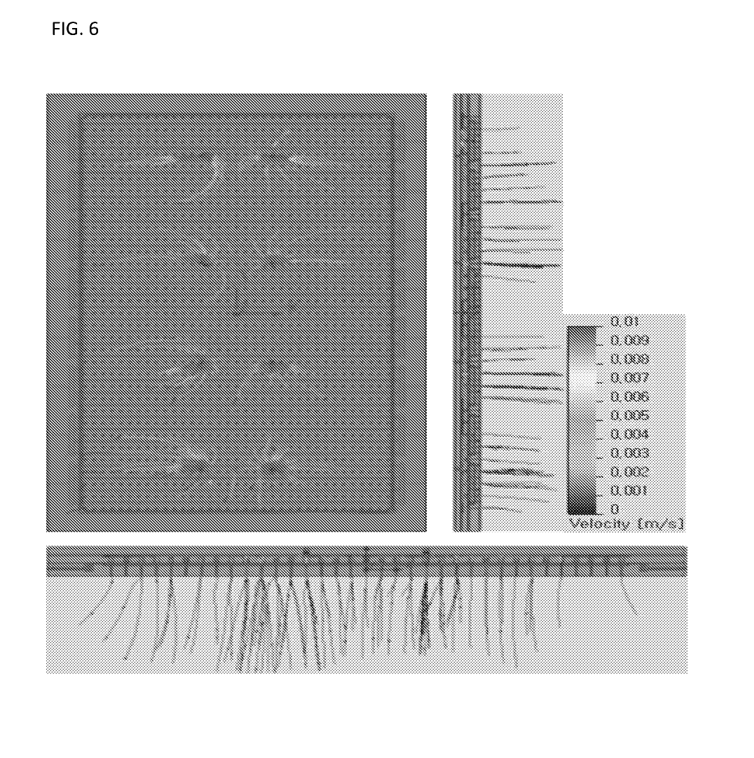

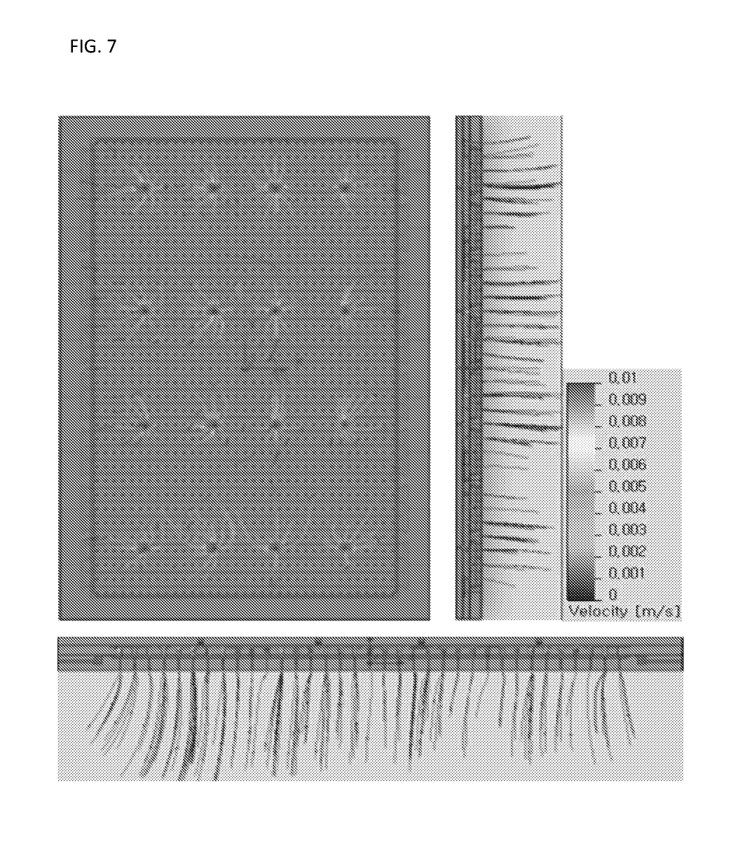

FIG. 6 is a figure showing simulation result of a gas sprayer having eight gas injection inputs according to an exemplary embodiment of the present invention and FIG. 7 is a figure showing a simulation result of a gas sprayer having sixteen gas injection inputs according to an exemplary embodiment of the present invention.

Referring to FIGS. 6 to 7, it is possible to see that a gas sprayed from sixteen gas injection inputs of FIG. 7 is more uniform than a gas sprayed from eight gas injection inputs of FIG. 6. In other words, in the conventional method, when a gas is sprayed through the center portion of the gas sprayer, amount of gas is much larger than that of sprayed through the lateral side, but by forming plurality of gas injection inputs and injecting gas through the plurality of gas injection inputs, it is possible to spray gas more uniformly, and further a uniformity is improved by increasing the number of gas injection inputs.

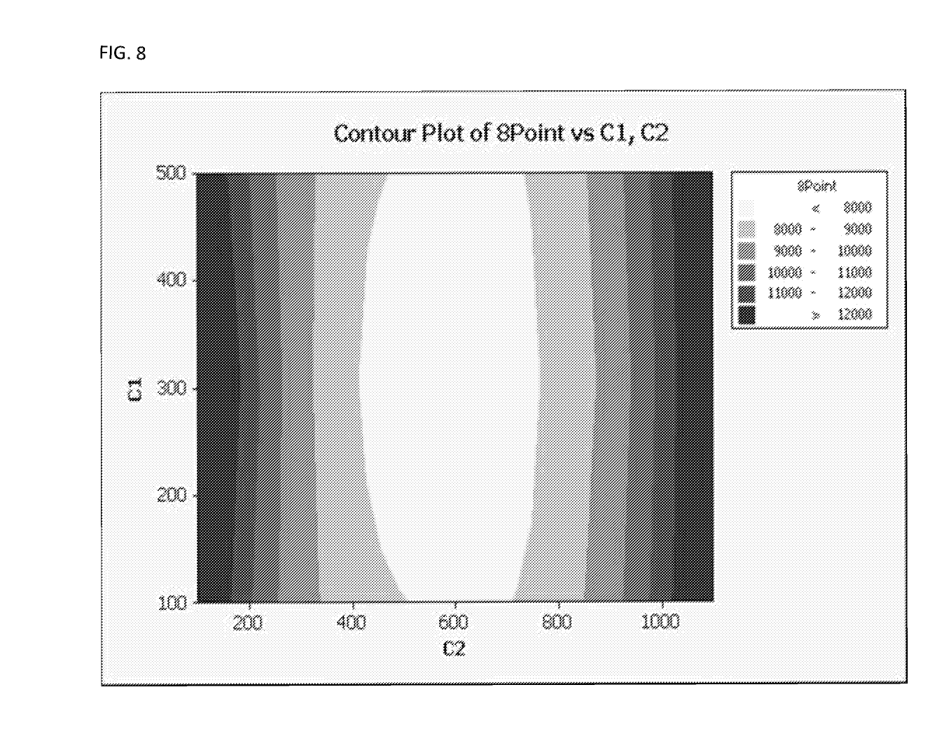

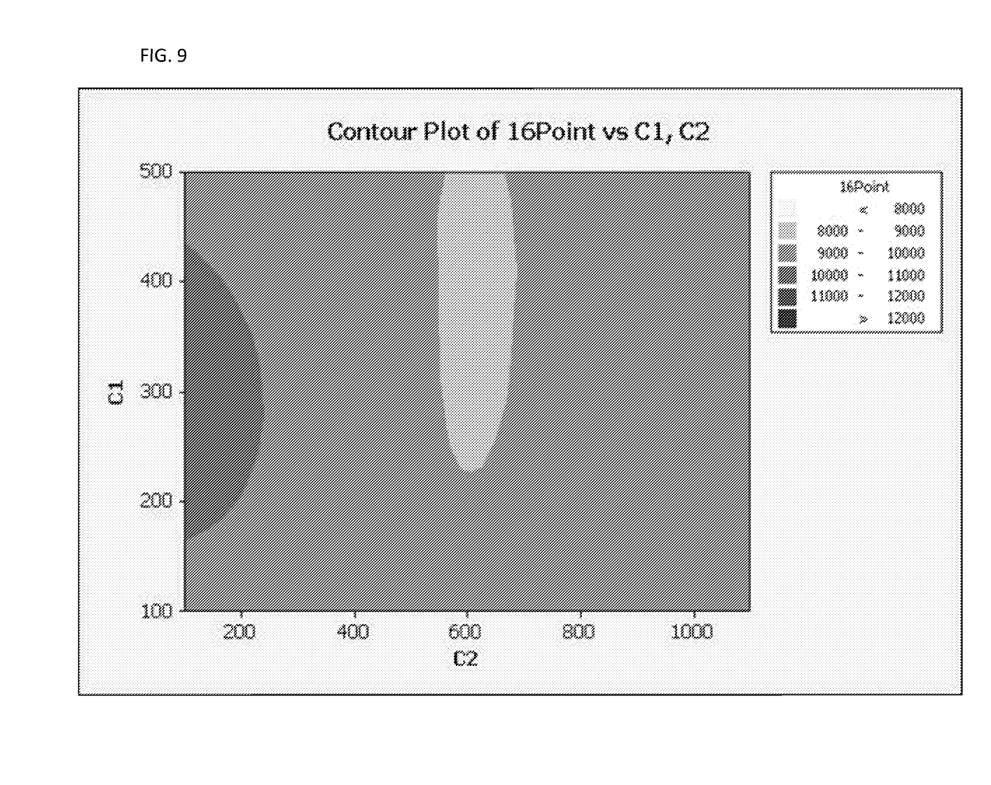

FIG. 8 is a figure showing simulated thickness result of thin film formed by a gas sprayer having eight gas injection inputs according to an exemplary embodiment of the present invention of FIG. 6, and FIG. 9 is a figure showing simulated thickness result of thin film formed by a gas sprayer having sixteen gas injection inputs according to an exemplary embodiment of the present invention of FIG. 7.

Referring to FIGS. 8 to 9, the number next to each color is an angstrom-scale A. In the case of FIG. 8, maximum thickness is 14,653 Å, minimum thickness is 7,535 Å, and average thickness is 10,424 Å, and in case of FIG. 9, maximum thickness is 10,322 Å, minimum thickness is 9,020 Å, and average thickness is 9,464 Å.

It may be seen that thickness of thin film deposited through eight gas injection inputs of FIG. 8 is uneven, but thickness of thin film deposited through sixteen gas injection inputs of FIG. 9 is relatively uniform. Therefore, it is predictable that uniformity improves when number of gas injection inputs increase.

According to a gas sprayer and thin film depositing apparatus of an embodiment of the present invention, when it is applied to a large sized substrate, it is possible to reduce diffusion time of gas within diffusion space by injecting gas to diffusion space through distrusted plurality of gas injection inputs without processing complex processing such as auxiliary diffusion space to distribute uniformly a gas.

It will be apparent to those skilled in the art that various modifications and variation may be made in the present invention without departing from the spirit or scope of the invention. Thus, it is intended that the present invention cover the modifications and variations of this invention provided they come within the scope of the appended claims and their equivalents.

<Code description>

| | |
|---|---|
| 100: gas sprayer | 110: upper plate |
| 111: first gas injection inputs | 112: second gas injection inputs |
| 120: bottom plate | 121: first plate |
| 121a: first hole | 122: second plate |
| 122a: second hole | 123: first gas spraying holes |
| 124: diffusion holes | 125: second gas spraying holes |
| 126: lateral diffusion space | 130: first pipe connecting structure |
| 131: first input | 132: first output |
| 140: second pipe connecting structure | 141: second input |
| 142: second output | 150: first connecting member |
| 151: first horizontal hole | 152: first vertical hole |
| 160: second connecting member | 161: second horizontal hole |
| 162: second vertical hole | 170: first screw |
| 180: second screw | 200: thin film depositing apparatus |
| 210: chamber | 220: substrate supporter |
| 310: first gas tank | 320: second gas tank |
| 330: third gas tank | 340 fourth gas tank |
| GDS: gas diffusion space | S: substrate to be treated |

1. A gas sprayer comprising:
an upper plate including a plurality of first gas injection inputs; and
a bottom plate coupled to the upper plate to form a diffusion space therebetween, wherein the bottom plate includes a first plurality of first gas spraying holes for spraying gas in the diffusion space which is injected through the plurality of first gas injection inputs.

2. The gas sprayer of claim 1, wherein the plurality of first gas injection inputs are arranged symmetrically with respect to each other.

3. The gas sprayer of claim 2, further comprising:
a first pipe connecting structure for injecting external gas to the plurality of first gas injection inputs, wherein a distance from a first input in which external gas is injected to the plurality of first gas injection inputs is identical in length.

4. The gas sprayer of claim 1, further comprising:
a first connecting member attached on upper surface of the upper plate to connect the upper surface of the upper plate and the first pipe connecting structure, wherein the first connecting member connects an output of the first pipe connecting structure to a plurality of first gas injection inputs.

5. The gas sprayer of claim 1, wherein the bottom plate further comprises:
a diffusion holes traversing both sides of the bottom plate between the first gas spraying holes, the both sides being opposite to each other; and
a second gas spraying holes for injecting gas of the diffusion holes into a lower portion.

6. The gas sprayer of claim 5, wherein the upper plate includes a plurality of second gas injection inputs, wherein the plurality of second gas injection inputs are connected to the diffusion holes.

7. The gas sprayer of claim 7, wherein the plurality of second gas injection inputs are formed symmetrically on both sides of the upper plate, the both sides being opposite to each other.

8. The gas sprayer of claim 7, further comprising:
a second pipe connecting structure for injecting external gas to the plurality of second gas injection inputs, wherein a distance from a second input in which external gas is injected to the plurality of second gas injection inputs is identical in length.

9. The gas sprayer of claim 7, further comprising:
a second connecting member attached on upper surface of the upper plate to connect the upper plate and the second pipe connecting structure, wherein the second connecting member connects an output of the second pipe connecting structure to the plurality of second gas injection inputs.

10. A thin film depositing apparatus comprising:
a chamber;
a substrate supporter supporting a substrate to be treated within the chamber; and
a gas sprayer disposed over the substrate supporter to spray gas toward the substrate supporter, and
wherein the gas sprayer comprises:
an upper plate including a plurality of first gas injection inputs arranged symmetrically; and
a bottom plate coupled to the upper plate to form a diffusion space therebetween, wherein the bottom plate comprises a first gas spraying holes for spraying gas in the diffusion space which is injected through the plurality of first gas injection inputs.

11. The thin film depositing apparatus of claim 10, wherein the gas sprayer further comprises a first pipe connecting structure for injecting external gas to the plurality of first gas injection inputs, wherein a distance from a first input in which external gas is injected to the plurality of first gas injection inputs is identical in length.

12. The thin film depositing apparatus of claim 11, further comprising:
a first tank storing a mixed gas with source gas and carrier gas; and
a second tank storing a mixed gas with carrier gas, and
wherein the first tank and the second tank are connected to a first input of the first pipe connecting structure through a valve through which flow rate is adjusted.

13. The thin film depositing apparatus of claim 10, wherein the bottom plate further comprises:
a diffusion holes traversing both sides of the bottom plate between the first gas spraying holes, the both sides being opposite to each other; and
a second gas spraying holes for injecting gas injected in the diffusion space into lower portion, and
wherein the upper plate comprises a plurality of second gas injection inputs connected to the diffusion holes.

14. The thin film depositing apparatus of claim 13, wherein the gas sprayer further comprises:
a second pipe connecting structure for injecting external gas to the plurality of second gas injection inputs, wherein a distance from a second input in which external gas is injected to the plurality of second gas injection inputs is identical in length.

15. The thin film depositing apparatus of claim 14, further comprising:
a third tank storing a mixed gas with source gas and carrier gas; and
a fourth tank storing a mixed gas with carrier gas, and
wherein the third tank and the fourth tank are connected to a second input of the second pipe connecting structure through a valve through which flow rate is adjusted.

16. The thin film depositing apparatus of claim 13, further comprising at least any one of the groups of a first to fourth tanks group or a fifth to eighth tanks group,
wherein,
the first and second tanks are connected to a portion of the plurality of first gas injection inputs in which a source gas and carrier gas are mixed and stored in the first tank and carrier gas is mixed and stored in the second tank, and the third and fourth tanks are connected to the remaining portion of the plurality of first gas injection inputs in which a source gas and carrier gas are mixed and stored in the third tank and carrier gas is mixed and stored in the fourth tank; and
the fifth and sixth tanks are connected to a portion of the plurality of second gas injection inputs in which a source gas and carrier gas are mixed and stored in the fifth tank and carrier gas is mixed and stored in the sixth tank, and a seventh and eighth tanks are connected to the remaining portion of the plurality of second gas injection inputs where a source gas and carrier gas are mixed and stored in the seventh tank and carrier gas is mixed and stored in the eighth tank.
